(19) United States
(12) Patent Application Publication
(10) Pub. No.: US 2026/0369262 A1
(43) Pub. Date: Nov. 19, 2026

(54) FULL-ANGLE SINGLE-MODE REFLECTOR FOR ELASTIC WAVE

(71) Applicant: Seoul National University R&DB Foundation, Seoul (KR)

(72) Inventors: Yoon Young KIM, Seoul (KR); Jooa PARK, Suwon-si (KR); Jeseung LEE, Anyang-si (KR)

(21) Appl. No.: 19/487,057

(22) PCT Filed: Dec. 18, 2023
(86) PCT No.: PCT/KR2023/020911

§ 371 Date: Mar. 6, 2026

(30) Foreign Application Priority Data
May 24, 2023 (KR) 10-2023-0067159

(51) Int. Cl. G10K 11/20

(52) U.S. Cl. CPC G10K 11/20

(57) ABSTRACT

An embodiment is to provide a full-angle single-mode reflector for elastic waves that can reflect only an elastic wave of the same mode as an incident wave mode, regardless of an incident condition of the elastic wave, by controlling a reflectance utilizing a reflective scattering matrix. A full-angle single-mode reflector for elastic waves is provided at a solid boundary on which an elastic wave including a longitudinal wave and a transverse wave is incident, includes an anisotropic medium having a predetermined reflectance and formed as a reflector so that an incident elastic wave is reflected under a full-angle single-mode reflection condition, calculates physical properties of the anisotropic medium by applying a predetermined reflective scattering matrix, and sets the reflectance of the anisotropic medium to the full-angle single-mode reflection condition by calculated physical properties of the anisotropic medium, thereby reflecting only an elastic wave of the same mode as an incident wave mode regardless of an incident condition of the elastic wave.

### TECHNICAL FIELD

A full-angle single-mode reflector for elastic waves is provided.

### BACKGROUND ART

Generally, in elastic waves, both a longitudinal wave and a transverse wave, which are two different wave modes, exist due to interatomic bonds constituting a medium. In the longitudinal wave, a propagation direction of the wave and a vibration direction of the medium are parallel to each other, and in the transverse wave shear wave, the propagation direction of the wave and the vibration direction of the medium are perpendicular to each other. When an elastic wave is incident on a solid boundary, both the longitudinal wave and the transverse wave are reflected. Such a multi-mode reflection phenomenon of the elastic wave may make signal processing at the solid boundary difficult. In addition, theories and technologies established in optics/acoustics in which only a single mode exists cannot be applied as they are to controlling elastic waves in which multi-modes exist.

In order to overcome the limitation due to the multi-mode reflection of elastic waves implementing the single-mode reflection of elastic waves, research implementing the single-mode reflection of elastic waves has been performed. When the elastic wave is vertically incident on the solid boundary, or when the transverse wave is incident on the solid boundary at an angle of incidence equal to or greater than a critical angle, only an elastic wave of the same wave mode as the incident wave mode may be reflected. Recently, research on selectively reflecting only a desired wave mode by utilizing metasurfaces or metagratings has also been reported. However, all of the above-described technologies operate limitedly only for specific incident conditions.

### DISCLOSURE

### Technical Problem

An embodiment is to provide a full-angle single-mode reflector of elastic waves that can reflect only an elastic wave of the same mode as an incident wave mode, regardless of an incident condition of the elastic wave, by controlling a reflectance utilizing a reflective scattering matrix.

### Technical Solution

A full-angle single-mode reflector of elastic waves according to an embodiment is provided at a solid boundary on which elastic waves including a longitudinal wave and a transverse wave are incident, includes an anisotropic medium having a predetermined reflectance and formed as a reflector so that the incident elastic waves are reflected under a full-angle single-mode reflection condition, calculates physical properties of the anisotropic medium by applying a predetermined reflective scattering matrix, and sets the reflectance of the anisotropic medium to the full-angle single-mode reflection condition by calculated physical properties of the anisotropic medium, thereby reflecting only an elastic wave of the same mode as the incident wave mode regardless of the incident condition of the elastic wave.

The anisotropic medium may include an elastic metamaterial in which a microstructure formed by adjusting a plurality of design variables is continuously arranged to form a repeating unit structure.

The microstructure may have a slit-shaped empty space. The microstructure may have a rectangular unit structure in a two-dimensional plane. The rectangular unit structure may include a plurality of slits erected at a vertical angle. The plurality of slits may have a symmetrical shape.

The unit structure may include a first slit provided at a center position, and two second slits respectively provided at positions corresponding to each other at an upper left side and an upper right side based on the first slit. In addition, the unit structure may include two third slits respectively provided at positions corresponding to each other at a lower left side and a lower right side based on the first slit.

The plurality of design variables may include a horizontal length Lₓ of the unit structure, a vertical length L_{y} of the unit structure, a width w of a pattern, a rectangular length l₁ of the first slit, a semicircle radius r₁ of the first slit, a rectangular length l₂ of the second slit, a semicircle radius r₂ of the second slit, a rectangular length Is of the third slit, and a semicircle radius r₃ of the third slit.

### Advantageous Effects

When an elastic wave is incident on a solid boundary by controlling reflectance utilizing a reflective scattering matrix, only an elastic wave of the same mode as an incident wave mode may be reflected regardless of an incident condition of the elastic wave.

### DESCRIPTION OF THE DRAWINGS

FIG. 1 is a diagram illustrating a situation in which only an elastic wave of the same wave mode as an incident wave mode is purely reflected regardless of an incident condition by utilizing an anisotropic medium having a reflectance according to an embodiment as a reflector.

FIG. 2 is a diagram illustrating reflectances of a longitudinal wave and a transverse wave according to an angle of incidence at a solid boundary when there is no anisotropic medium according to an embodiment.

FIG. 3 is a diagram illustrating reflectances of a longitudinal wave and a transverse wave according to an angle of incidence in the case of an anisotropic medium according to an embodiment.

FIG. 4 is a diagram illustrating a microstructure of a full-angle single-mode reflector according to an embodiment.

FIG. 5 is a diagram illustrating reflectances of a longitudinal wave and a transverse wave according to an angle of incidence of an anisotropic medium according to an embodiment.

FIG. 6 is a diagram illustrating a reflected longitudinal wave field and a reflected transverse wave field, respectively, when a longitudinal wave is incident.

FIG. 7 is a diagram illustrating a reflected longitudinal wave field and a reflected transverse wave field, respectively, when a transverse wave is incident.

### MODE FOR INVENTION

The terminology used herein is for the purpose of describing particular embodiments only and is not intended to be limiting of the invention. The singular forms used herein include plural forms as well, unless the context clearly indicates otherwise. The meaning of “comprising” used in the specification specifies a specific feature, region, integer, step, operation, element, and/or component, and does not exclude the presence or addition of other specific features, regions, integers, steps, operations, elements, components, and/or groups.

Unless otherwise defined, all terms including technical and scientific terms used herein have the same meaning as commonly understood by one of ordinary skill in the art to which this invention belongs. Commonly used predefined terms are further interpreted to have a meaning consistent with the relevant technical literature and the presently disclosed content, and are not to be interpreted in an idealized or overly formal sense unless explicitly defined.

Hereinafter, embodiments of the present invention will be described in detail with reference to the accompanying drawings so that those skilled in the art to which the present invention pertains may easily practice them. However, the present invention may be embodied in many different forms and is not limited to the embodiments described herein.

According to an embodiment, by controlling the reflectance of an anisotropic medium 100 utilizing a reflective scattering matrix to form the anisotropic medium 100 as a reflector such that an elastic wave incident on a solid boundary 10a is reflected under a full-angle single-mode reflection condition, only an elastic wave of the same mode as the incident wave mode may be reflected regardless of the incident condition of the elastic wave.

However, according to the prior art, research on controlling transmittance and reflectance through a transmissive scattering matrix has been reported, and such a transmissive scattering matrix can be utilized only for a situation in which a transmissive medium exists.

Unlike the prior art, according to an embodiment, a reflective scattering matrix that does not have a transmissive medium and controls a reflectance at the solid boundary 10a is provided. Through this, the anisotropic medium 100 may be designed to have a target reflectance by calculating the reflectance.

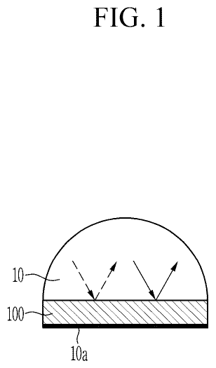

A full-angle single-mode reflector of elastic waves according to an embodiment may implement a full-angle single-mode reflection phenomenon reflecting only an elastic wave of the same wave mode as an incident wave mode with respect to all angles of incidence and all incident modes, by applying an anisotropic medium 100 having a target reflectance as a reflector by utilizing a reflective scattering matrix. A conceptual diagram thereof is shown in FIG. 1.

FIG. 1 is a diagram illustrating a situation in which only an elastic wave of the same wave mode as an incident wave mode is purely reflected regardless of an incident condition by utilizing an anisotropic medium 100 having a reflectance according to an embodiment as a reflector.

An embodiment presents a mathematical condition that physical properties ρ, C₁₁, C₁₂, C₁₆, C₂₂, C₂₆, C₆₆ of the anisotropic medium 100 must satisfy to implement a full-angle single-mode reflection phenomenon through a reflective scattering matrix. Here, a frequency of the incident elastic wave, physical properties of the isotropic background medium 10, and a thickness of the anisotropic medium 100 are predetermined. Generally, the scattering matrix is denoted by S, but here it is denoted by J to distinguish it from the transmissive scattering matrix.

A boundary between the background medium 10 to which the elastic wave is incident and the anisotropic medium 100 is referred to as x=0, and the solid boundary 10a is referred to as x=d. Equations 1.1 to 1.3 represent a stress field at x=0 when a longitudinal wave is incident.

$${[ \begin{matrix}{v}_{x} \\ {v}_{y} \\ {σ}_{x x} \\ {σ}_{x y}\end{matrix} ]}_{x = {0}^{+}} = {M}_{ani} [ \begin{matrix}A \\ B \\ C \\ D\end{matrix} ] \qquad [ Equation 1.1 ]$$

$${[ \begin{matrix}{v}_{x} \\ {v}_{y} \\ {σ}_{xx} \\ {σ}_{xy}\end{matrix} ]}_{x = {0}^{−}} = {M}_{iso} [ \begin{matrix}1 \\ {r}_{L} \\ 0 \\ {r}_{T}\end{matrix} ] \qquad [ Equation 1.2 ]$$

$$[ Equation 1.3 ]$$

$${M}_{i , 11} = − j ω {P}_{x}^{a} , {M}_{i , 12} = − j ω {P}_{x}^{b} , {M}_{i , 23} , j ω {P}_{x}^{c} , {M}_{i , 14} = - j ω {P}_{x}^{d} ,$$

$${M}_{i , 21} = − j ω {P}_{y}^{a} , {M}_{i , 22} = − j ω {P}_{y}^{b} , {M}_{i , 23} , j ω {P}_{x}^{c} , {M}_{i , 24} = - j ω {P}_{y}^{d} ,$$

$${M}_{i , 31} = j {k}_{x}^{a} ( {C}_{11}^{i} {P}_{x}^{a} + {C}_{16}^{i} {P}_{y}^{a} ) + j σ ( {C}_{12}^{i} {P}_{y}^{a} + {C}_{16}^{d} {P}_{x}^{a} ) ,$$

$${M}_{i , 32} = j {k}_{x}^{b} ( {C}_{11}^{i} {P}_{x}^{b} + {C}_{16}^{i} {P}_{y}^{b} ) + j σ ( {C}_{12}^{i} {P}_{y}^{b} + {C}_{16}^{i} {P}_{x}^{b} ) ,$$

$${M}_{i , 33} = j {k}_{x}^{c} ( {C}_{11}^{i} {P}_{x}^{c} + {C}_{16}^{i} {P}_{y}^{c} ) + j σ ( {C}_{12}^{i} {P}_{y}^{c} + {C}_{16}^{i} {P}_{x}^{c} ) ,$$

$${M}_{i , 34} = j {k}_{x}^{d} ( {C}_{11}^{i} {P}_{x}^{d} + {C}_{16}^{i} {P}_{y}^{d} ) + j σ ( {C}_{12}^{i} {P}_{y}^{d} + {C}_{16}^{i} {P}_{x}^{d} ) ,$$

$${M}_{i , 41} = j {k}_{x}^{a} ( {C}_{16}^{i} {P}_{x}^{a} + {C}_{66}^{i} {P}_{y}^{a} ) + j σ ( {C}_{26}^{i} {P}_{y}^{a} + {C}_{66}^{i} {P}_{x}^{a} ) ,$$

$${M}_{i , 42} = j {k}_{x}^{b} ( {C}_{16}^{i} {P}_{x}^{b} + {C}_{66}^{i} {P}_{y}^{b} ) + j σ ( {C}_{26}^{i} {P}_{y}^{b} + {C}_{66}^{i} {P}_{x}^{b} ) ,$$

$${M}_{i , 43} = j {k}_{x}^{c} ( {C}_{16}^{i} {P}_{x}^{c} + {C}_{66}^{i} {P}_{y}^{c} ) + j σ ( {C}_{26}^{i} {P}_{y}^{c} + {C}_{66}^{i} {P}_{x}^{c} ) ,$$

$${M}_{i , 44} = j {k}_{x}^{d} ( {C}_{16}^{i} {P}_{x}^{d} + {C}_{66}^{i} {P}_{y}^{d} ) + j σ ( {C}_{26}^{i} {P}_{y}^{d} + {C}_{66}^{i} {P}_{x}^{d} ) ,$$

Equations 2.1 and 2.2 represent a stress field at x=d.

$${[ \begin{matrix}{v}_{x} \\ {v}_{y} \\ {σ}_{x x} \\ {σ}_{x y}\end{matrix} ]}_{x = {d}^{−}} = {M}_{ani} {N}_{x = d} [ \begin{matrix}A \\ B \\ C \\ D\end{matrix} ] \qquad [ Equation 2.1 ]$$

$${N}_{x = d} = [ \begin{matrix}{e}^{j {k}_{x}^{{QL}^{+}} d} & 0 & 0 & 0 \\ 0 & {e}^{j {k}_{x}^{{QL}^{-}} d} & 0 & 0 \\ 0 & 0 & {e}^{j {k}_{x}^{{QS}^{+}} d} & 0 \\ 0 & 0 & 0 & {e}^{j {k}_{x}^{{QS}^{−}} d}\end{matrix} ] \qquad [ Equation 2.2 ]$$

When Equations 1.1 to 1.3, and Equations 2.1 and 2.2 are combined, a J matrix may be expressed. Utilizing a solid free stress boundary, all stresses at x=d become 0, so that Equation 3 may be derived.

$${[ \begin{matrix}{v}_{x} \\ {v}_{y} \\ 0 \\ 0\end{matrix} ]}_{x = {d}^{-}} = {M}_{ani} {N}_{x = d} {M}_{ani}^{− 1} {M}_{i s o} [ \begin{matrix}1 \\ {r}_{L} \\ 0 \\ {r}_{T}\end{matrix} ] = J [ \begin{matrix}1 \\ {r}_{L} \\ 0 \\ {r}_{T}\end{matrix} ] \qquad [ Equation 3 ]$$

A reflection coefficient may be calculated by a combination of the J matrix, which is expressed by Equation 4.

$${r}_{LL} = \frac{{J}_{31} {J}_{44} − {J}_{34} {J}_{41}}{{J}_{34} {J}_{42} − {J}_{32} {J}_{44}} , {r}_{LT} = \frac{{J}_{32} {J}_{41} − {J}_{31} {J}_{42}}{{J}_{34} {J}_{42} − {J}_{32} {J}_{44}} \qquad [ Equation 4 ]$$

Even for a case in which a transverse wave is incident, when the same process as above is performed, the reflection coefficient may be expressed by

### Equation 5.

$${r}_{T L} = \frac{{J}_{33} {J}_{44} − {J}_{34} {J}_{43}}{{J}_{34} {J}_{42} − {J}_{34} {J}_{42}} , {r}_{T T} = \frac{{J}_{32} {J}_{43} − {J}_{33} {J}_{42}}{{J}_{34} {J}_{42} − {J}_{34} {J}_{42}} \qquad [ Equation 5 ]$$

Utilizing the reflection coefficient and power intensity calculated from Equation 4 and Equation 5, the reflectance may be expressed by Equations 6.1 to 6.4.

$${R}_{LL} = {\vert {r}_{LL} \vert}^{2} \qquad [ Equation 6.1 ]$$

$${R}_{T T} = {\vert {r}_{T T} \vert}^{2} \qquad [ Equation 6.2 ]$$

$${R}_{L T} = \frac{\sqrt{{C}_{66}} cos {θ}_{T}}{\sqrt{{C}_{11}} cos {θ}_{L}} {\vert {r}_{L T} \vert}^{2} \qquad [ Equation 6.3 ]$$

$${R}_{T L} = \frac{\sqrt{{C}_{11}} cos {θ}_{L}}{\sqrt{{C}_{66}} cos {θ}_{T}} {\vert {r}_{T L} \vert}^{2} \qquad [ Equation 6.4 ]$$

Here, since the reflectance may be adjusted by the physical properties of the anisotropic medium 100, when the reflectance to a mode different from the incident mode is controlled to 0, physical properties of the anisotropic medium 100 reflecting only to the same mode as the incident mode according to an embodiment may be designed.

The full-angle single-mode reflector of elastic waves according to an embodiment may implement a full-angle single-mode reflection phenomenon of elastic waves regardless of incident conditions (incident angle and incident mode) by utilizing the anisotropic medium 100 having elliptical frequency contours as a reflector.

However, when the prior art is utilized, a single-mode reflection phenomenon can be implemented only limitedly for a situation in which a longitudinal wave or a transverse wave is vertically incident on the solid boundary 10a or a transverse wave having an incident angle greater than or equal to a critical angle is obliquely incident.

Unlike the prior art, when an embodiment is utilized, a single-mode reflection phenomenon can be implemented regardless of the incident condition of the elastic wave, so that the traditional limit of reflected wave control technology at the solid boundary 10a may be overcome.

Utilizing an embodiment, it is possible to purely reflect only an elastic wave of the same wave mode as the incident wave mode regardless of the incident condition (incident angle, incident wave mode) of the elastic wave. There may be various types of solid boundary 10a conditions, but an embodiment primarily deals with a stress-free boundary condition. The concept according to an embodiment may also be extended to other solid boundary conditions.

In an embodiment, when the background medium 10 into which an elastic wave is incident is made of an aluminum material, physical properties of the anisotropic medium 100 satisfying all of the mathematical conditions (Equations 1.1 to 1.3, Equations 2.1 and 2.2, Equation 3) for implementing a full-angle single-mode reflection phenomenon according to an embodiment may be presented. An embodiment assumes a plane-stress condition. The physical properties of aluminum are ρ=2700 kg/m³, C₁₁=78.555 GPa, C₁₂=25.923 GPa, C₁₆=0 GPa, C₂₂=78.555 GPa, C₂₆=0 GPa, and C₆₆=26.316 GPa. The physical properties of the anisotropic medium 100 are ρ=2535.5 kg/m³, C₁₁=111.74 GPa, C₁₂=−26.656 GPa, C₁₆=0 GPa, C₂₂=16.526 GPa, C₂₆=0 GPa, and C₆₆=26.656 GPa.

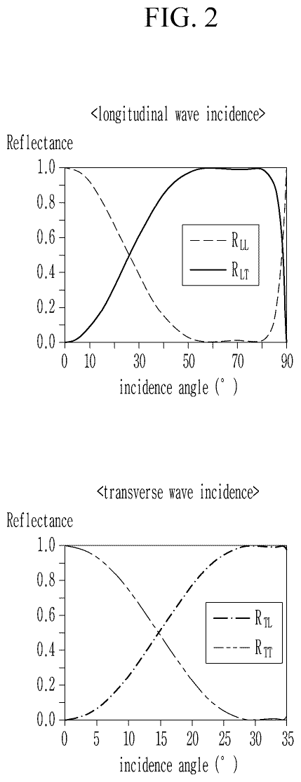

FIG. 2 is a diagram illustrating reflectances of a longitudinal wave and a transverse wave according to an angle of incidence at the solid boundary 10a when there is no anisotropic medium 100 according to an embodiment. When a longitudinal wave is incident, a longitudinal wave and a transverse wave are simultaneously reflected, and when a transverse wave is incident, a longitudinal wave and a transverse wave are simultaneously reflected below a critical angle.

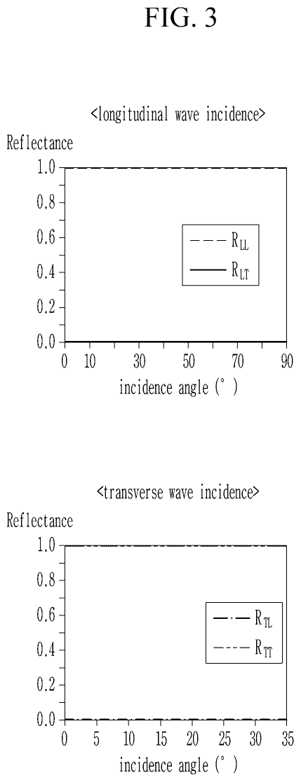

FIG. 3 is a diagram illustrating reflectances of a longitudinal wave and a transverse wave according to an angle of incidence of the anisotropic medium 100 according to an embodiment. When a longitudinal wave is incident, the reflectance of the longitudinal wave is 100% for all incident angles, and when a transverse wave is incident, the reflectance of the transverse wave is 100% for all incident angles below the critical angle. For an angle of incidence equal to or greater than the critical angle, the reflectance of the transverse wave is obviously 100%. In other words, when the anisotropic medium 100 according to an embodiment is utilized, a full-angle single-mode reflection phenomenon may be implemented.

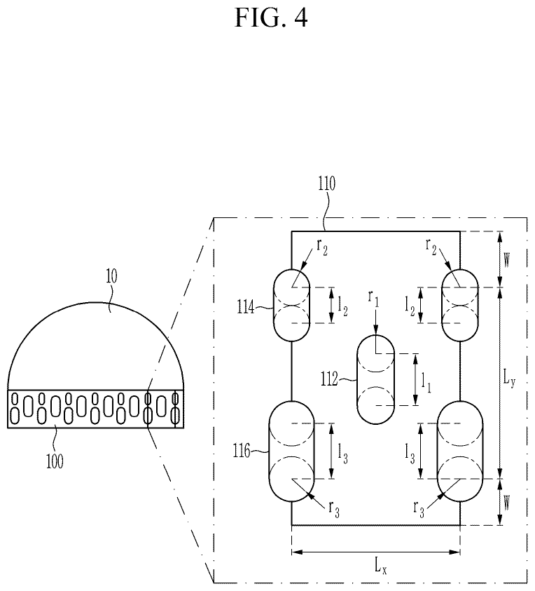

The anisotropic medium 100 according to an embodiment may be implemented utilizing elastic metamaterials. An embodiment proposes an elastic metamaterial microstructure of a novel shape pattern capable of effectively implementing the anisotropic medium 100. A conceptual diagram thereof is shown in FIG. 4.

FIG. 4 is a diagram illustrating a microstructure of a full-angle single-mode reflector according to an embodiment. A constituent material of the reflector can be freely selected, and shape patterns included in the microstructure may be provided in a hole shape through mechanical processing. The microstructure has a slit-shaped empty space in which semicircles are provided at both ends of a rectangle in a longitudinal direction. The microstructure has a rectangular unit structure in a two-dimensional plane. The rectangular unit structure includes a plurality of slits elongated vertically, and the plurality of slits may be provided in a symmetrical shape.

Referring to FIG. 4, the microstructure may be arranged in a symmetrical structure with four slits of different sizes respectively provided at both sides around one slit in a rectangular unit structure 110. The five slits provided in the unit structure 110 include a first slit 112 provided at a center position, two second slits 114 respectively provided at positions corresponding to each other at an upper left side and an upper right side based on the first slit 112, and two third slits 116 respectively provided at positions corresponding to each other at a lower left side and a lower right side based on the first slit 112. The two second slits 114 and the two third slits 116 may be formed in the same shape as each other. The second slit 114 and the third slit 116 may be provided at positions where both sides are divided relative to a center line along a longitudinal direction of the first slit 112.

Design variables possessed by the microstructure include a horizontal length Lₓ of the unit structure 110, a vertical length L_{y} of the unit structure 110, a width w of the pattern, a length l₁ of a rectangular portion in the first slit 112, a radius r₁ of a semicircular portion in the first slit 112, a length l₂ of a rectangular portion in the second slit 114, a radius r₂ of a semicircular portion in the second slit 114, a length Is of a rectangular portion in the third slit 116, and a radius r₃ of a semicircular portion in the third slit 116. When all 9 design variables of the microstructure are appropriately adjusted, an anisotropic medium 100 implementing a full-angle single-mode reflection phenomenon may be designed.

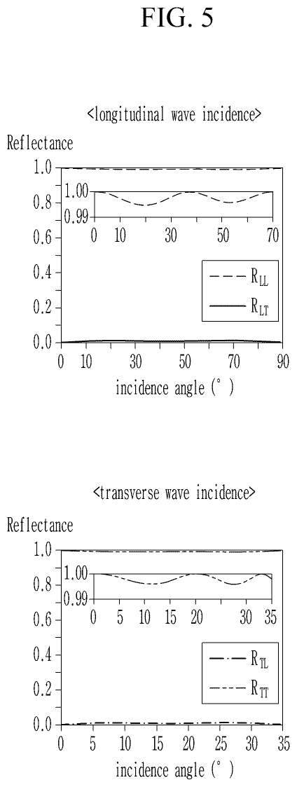

According to an embodiment, a microstructure of an anisotropic medium 100 implementing a full-angle single-mode reflection phenomenon and simulation analysis results are presented. In an embodiment, without losing generality, it is assumed that the isotropic background medium 10 is aluminum, a frequency of an incident elastic wave is 100 kHz, and a thickness of the anisotropic medium 100 is 20 mm. The design results are as follows. Lₓ=10 mm, L_{y}=10 mm, w=5 mm, l₁=4.97 mm, r₁=1.60 mm, l₂=1.07 mm, l₂=2.24 mm, l₃=2.38 mm, and r₃=1.43 mm. Simulation analysis results depending on presence or absence of an anisotropic medium 100 according to an embodiment under a stress-free boundary condition are shown in FIGS. 5, 6, and 7, respectively.

FIG. 5 is a diagram illustrating reflectances of a longitudinal wave and a transverse wave according to an angle of incidence of the anisotropic medium 100 according to an embodiment. When a longitudinal wave is incident, the reflectance of the longitudinal wave is 99% or more for all incident angles, and when a transverse wave is incident, the reflectance of the transverse wave is 99% or more for all incident angles below the critical angle. For an angle of incidence equal to or greater than the critical angle, the reflectance of the transverse wave is obviously 99% or more. Accordingly, when the anisotropic medium 100 according to an embodiment is utilized, a full-angle single-mode reflection phenomenon may be implemented.

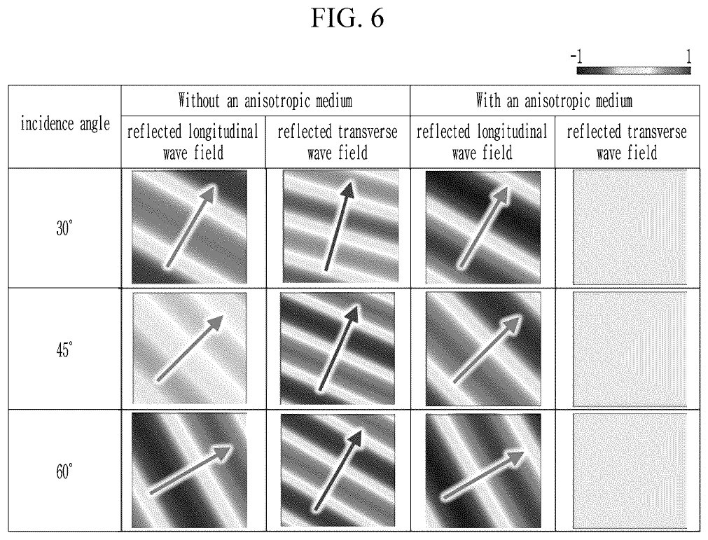

FIG. 6 is a diagram illustrating a reflected longitudinal wave field and a reflected transverse wave field, respectively, when a longitudinal wave is incident. When there is no anisotropic medium 100 according to an embodiment, it is confirmed that both a longitudinal wave and a transverse wave are reflected at a solid boundary 10a. However, when the anisotropic medium 100 according to an embodiment is present, a simulation analysis result confirms that only a longitudinal wave is purely reflected through the fact that a reflected transverse wave field does not exist and only a reflected longitudinal wave field exists for all incident angles. Such a simulation result supports that full-angle single-mode reflection may be implemented through the anisotropic medium 100 according to an embodiment.

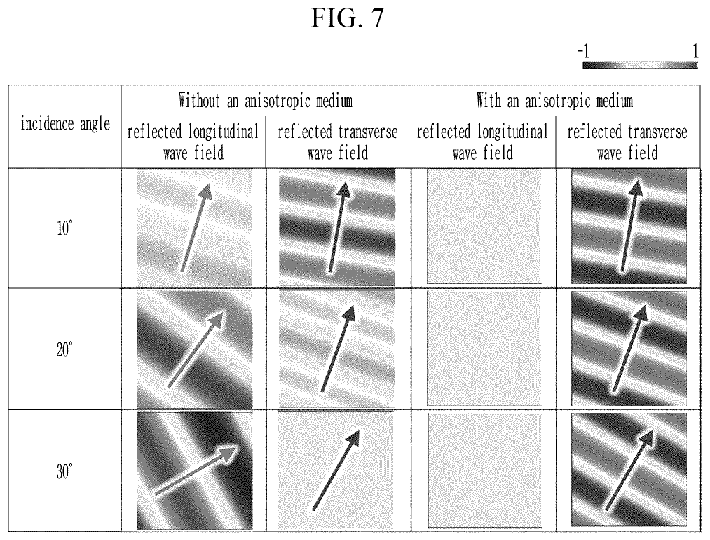

FIG. 7 is a diagram illustrating a reflected longitudinal wave field and a reflected transverse wave field, respectively, when a transverse wave is incident. When there is no anisotropic medium 100 according to an embodiment, it is confirmed that both a longitudinal wave and a transverse wave are reflected at the solid boundary 10a. When incident at 30 degrees, it is confirmed that all incident transverse waves are reflected as longitudinal waves. However, when the anisotropic medium 100 according to an embodiment is present, a simulation analysis result confirms that only a transverse wave is purely reflected through the fact that a reflected longitudinal wave field does not exist and only a reflected transverse wave field exists for an incident angle less than a critical angle. Such a simulation result supports that full-angle single-mode reflection may be implemented through the anisotropic medium 100 according to an embodiment.

As described above, an embodiment applies an anisotropic medium 100 capable of controlling a reflectance by utilizing a reflective scattering matrix as a reflector, so that when an elastic wave is incident on the solid boundary 10a, it can purely reflect only an elastic wave of the same wave mode as the incident wave mode regardless of an incident condition (incident angle, incident wave mode) of the elastic wave. Accordingly, an embodiment may implement a full-angle single-mode reflection phenomenon of an elastic wave by utilizing a reflective scattering matrix and using an anisotropic medium 100 to have a target reflectance.

Although preferred embodiments of the present invention have been described above, the present invention is not limited thereto, and it is possible to carry out various modifications within the scope of the claims, the detailed description of the invention, and the accompanying drawings, and it is a matter of course that this also belongs to the scope of the present invention.

1. The full-angle single-mode reflector for elastic wave comprising:
an anisotropic medium provided at a solid boundary on which an elastic wave including a longitudinal wave and a transverse wave is incident, having a predetermined reflectance, and formed as a reflector so that an incident elastic wave is reflected under a full-angle single-mode reflection condition,
wherein the full-angle single-mode reflector for elastic wave calculates physical properties of the anisotropic medium by applying a predetermined reflective scattering matrix, and reflects only an elastic wave of the same mode as an incident wave mode regardless of an incident condition of the elastic wave, by setting a reflectance of the anisotropic medium to the full-angle single-mode reflection condition by calculated physical properties of the anisotropic medium.

2. The full-angle single-mode reflector for elastic wave of claim 1, wherein the anisotropic medium includes an elastic metamaterial in which a microstructure formed by adjusting a plurality of design variables is continuously arranged to form a repeating unit structure.

3. The full-angle single-mode reflector for elastic wave of claim 2, wherein the microstructure has a slit-shaped empty space.

4. The full-angle single-mode reflector for elastic wave of claim 3, wherein the microstructure has a rectangular unit structure in a two-dimensional plane, the rectangular unit structure includes a plurality of slits erected at a vertical angle, and the plurality of slits has a symmetrical shape.

5. The full-angle single-mode reflector for elastic wave of claim 4, wherein the unit structure comprises:
a first slit provided at a center position,
two second slits respectively provided at positions corresponding to each other at an upper left side and an upper right side based on the first slit, and
two third slits respectively provided at positions corresponding to each other at a lower left side and a lower right side based on the first slit.

6. The full-angle single-mode reflector for elastic wave of claim 5, wherein the plurality of design variables include a horizontal length Lₓ of the unit structure, a vertical length L_{y} of the unit structure, a width w of a pattern, a rectangular length l₁ of the first slit, a semicircle radius r₁ of the first slit, a rectangular length l₂ of the second slit, a semicircle radius r₂ of the second slit, a rectangular length Is of the third slit, and a semicircle radius r₃ of the third slit.
